(19) United States
(12) Patent Application Publication
(10) Pub. No.: US 2024/0118608 A1
(43) Pub. Date: Apr. 11, 2024

(54) DEVICE AND METHOD FOR PHOTOMASK CLEANING AND FLIPPING

(71) Applicants: Chun-Jung Chiu, New Taipei City (TW); Chun-Hsiung Chen, New Taipei City (TW); Wan-Chen Chuang, New Taipei City (TW)

(72) Inventors: Chun-Jung Chiu, New Taipei City (TW); Chun-Hsiung Chen, New Taipei City (TW); Wan-Chen Chuang, New Taipei City (TW)

(21) Appl. No.: 18/375,984

(22) Filed: Oct. 2, 2023

(30) Foreign Application Priority Data
Oct. 11, 2022 (TW) 111138408

(51) Int. Cl. G03F 1/82

(52) U.S. Cl. CPC G03F 1/82

(57) ABSTRACT

The present disclosure pertains to a photomask cleaning device suitable for cleaning a photomask. The interior of the photomask cleaning device is equipped with a cleaning area and a photomask flipping area. The photomask has a first surface and a second surface, with a pattern and a photomask protective film set on the first surface. The photomask protective film covers the pattern. The photomask cleaning device includes a photomask flipping mechanism, a transport mechanism, and at least one cleaning mechanism. The photomask flipping mechanism is located within the photomask flipping area and is configured to flip the photomask. Additionally, the transport mechanism is used to transport the photomask, enabling the photomask to move between the photomask flipping area and the cleaning area. The cleaning mechanism is located within the cleaning area and is used to clean the photomask.

### TECHNICAL FIELD

The present disclosure pertains to a photomask cleaning device, a photomask flipping mechanism, and a photomask cleaning method, specifically referring to a device, mechanism, and method for cleaning contaminants from the protective film of a photomask.

### BACKGROUND

In the semiconductor manufacturing process, it includes an exposure process, which first places a photomask with a pattern above a wafer, then uses an exposure light source to project the pattern on the photomask onto a wafer. Afterwards, the wafer is immersed in a developer solution to reveal the pattern of the photomask on the wafer.

A photomask protective film is present on the photomask, the photomask protective film is located on the side of the photomask that has a pattern, to prevent the pattern on the photomask from being scratched by contaminants. In addition, because the photomask protective film can adhere contaminants due to static electricity, such as fine particles, it is therefore, necessitated to clean the photomask protective film, so as not to affect the yield of the semiconductor process. However, as today's semiconductor processes become more and more refined, entering the nano era, the photomask protective film also has to be thinned. Therefore, if you just clean the photomask protective film and do not clean the other side of the photomask, the contaminants on the other side of the photomask can easily adhere to the photomask protective film with the flow of air, or enter between the photomask protective film and the photomask.

For example, TWI576657 discloses a photomask cleaning device and a photomask cleaning method, which separates the photomask protective film and contaminants on the photomask through an ultrasonic device and a static elimination controller, and then cleans the photomask protective film through a jet device and a liquid cleaning device. However, if you want to clean the other side without the photomask protective film, you will have to remove the photomask from the photomask cleaning device, manually flip the photomask, and then send it back to the photomask cleaning device for cleaning. For another example, the photomask cleaning device disclosed in TWI760133 includes a transport device, which can transport the photomask to the outside of the main body of the photomask cleaning device for the producer to flip the photomask. However, manually flipping the photomask not only has lower efficiency, but also flipping the photomask outside the photomask cleaning device may bring new contaminants.

Therefore, how to improve the above problems is worth considering for those with ordinary knowledge in this field.

### SUMMARY

The purpose of the present disclosure is to provide a photomask cleaning device that aids in cleaning both the first and second surfaces of the photomask.

The photomask cleaning device of the present disclosure is suitable for cleaning a photomask. The interior of the photomask cleaning device is equipped with a cleaning area and a photomask flipping area. The photomask has a first surface and a second surface, and a pattern and a photomask protective film are set on the first surface. The photomask protective film covers the pattern. The photomask cleaning device includes a photomask flipping mechanism, a transport mechanism, and at least one cleaning mechanism. The photomask flipping mechanism is located within the photomask flipping area and is used to flip the photomask. In addition, the transport mechanism is used to transport the photomask, enabling the photomask to move between the photomask flipping area and the cleaning area. The cleaning mechanism is located within the cleaning area and is used to clean the photomask.

In the aforementioned photomask cleaning device, the photomask flipping mechanism includes a first arm, a second arm, and a flipping part. The first arm includes a first holding part, the second arm includes a second holding part, and the first arm and the second arm can move relative to one another. In addition, the flipping part connects the first arm and the second arm, and the flipping part can flip the first arm and the second arm. The second arm can move horizontally relative to the first arm, and the flipping part connects the first arm and the second arm.

In the aforementioned photomask cleaning device, the photomask flipping mechanism also includes a lifting mechanism, and the lifting mechanism connects the flipping part of the photomask flipping mechanism.

In the aforementioned photomask cleaning device, the transport mechanism includes a rail and a photomask carrier. The rail connects the photomask flipping area and the cleaning area. In addition, the photomask carrier is assembled on the rail in a movable manner, and the photomask is carried on the photomask carrier.

In the aforementioned photomask cleaning device, the cleaning mechanism includes at least one of an air knife device, a static neutralization device, or an ultrasonic resonance device.

Another purpose of the present disclosure is to provide a photomask flipping mechanism that aids in cleaning both the first and second surfaces of the photomask.

The photomask flipping mechanism of the present disclosure is suitable for flipping a photomask. The photomask has a first surface and a second surface, and a pattern and a photomask protective film are set on the first surface. The photomask protective film covers the pattern. The photomask flipping mechanism includes a first arm, a second arm, and a flipping part. The first arm includes a first holding part, and the second arm includes a second holding part. In addition, the flipping part connects the first arm and the second arm, and the flipping part can flip the first arm and the second arm. The first arm and the second arm can move relative to one another, enabling the first holding part and the second holding part to hold the photomask.

In the aforementioned photomask flipping mechanism, the flipping part includes a rotating part and a support part. The support part is connected to the rotating part, and the rotating part can flip the support part.

In the aforementioned photomask flipping mechanism, the first arm is located on one side of the support part, and the second arm is located on the other side of the support part.

In the aforementioned photomask flipping mechanism, the support part includes a body, a first telescopic member, and a second telescopic member. One end of the first telescopic member is connected to the body, and the other end of the first telescopic member is connected to the first arm. In addition, one end of the second telescopic member is connected to the body, and the other end of the second telescopic member is connected to the second arm.

In the aforementioned photomask flipping mechanism, it also includes a first dust-free cushion and a second dust-free cushion. The first dust-free cushion and the second dust-free cushion are respectively arranged on the first holding part and the second holding part, and when the photomask flipping mechanism holds the photomask, the first dust-free cushion and the second dust-free cushion are in contact with the photomask.

In the aforementioned photomask flipping mechanism, the distance between the first holding part and the second holding part is less than the average distance between the first arm and the second arm.

In the aforementioned photomask flipping mechanism, the first holding part and the second holding part are parallel to one another.

In the aforementioned photomask flipping mechanism, at least one pressure sensor is arranged on the first arm or the second arm.

Another purpose of the present disclosure is to provide a photomask cleaning method that aids in cleaning both the first and second surfaces of the photomask.

The photomask cleaning method of the present disclosure uses the aforementioned photomask flipping mechanism to clean a photomask. A photomask protective film is set on the first surface of the photomask. The photomask cleaning method includes the following steps: first, move the photomask with the second surface facing up into a cleaning area. Then, clean the second surface of the photomask in the cleaning area. Next, move the photomask out of the cleaning area. Then, flip the photomask via the photomask flipping mechanism to make the first surface of the photomask face up. Next, move the photomask into the cleaning area. Then, clean the photomask protective film on the first surface of the photomask. Next, move the photomask out of the cleaning area. Then, flip the photomask via the photomask flipping mechanism to make the first surface of the photomask face down.

In the aforementioned photomask cleaning method, the photomask is moved into and out of the cleaning area via a transport mechanism.

The present disclosure has the following advantages: it can thoroughly clean both the first and second surfaces of the photomask.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1A illustrates a schematic diagram of the photomask cleaning device 1 in this implementation.

FIG. 1B illustrates a schematic diagram of the photomask flipping mechanism 10 in this implementation.

FIG. 1C illustrates a three-dimensional diagram of the photomask flipping mechanism 10.

FIG. 1D illustrates a schematic diagram of the photomask 8.

FIG. 2A illustrates a schematic diagram of the first arm 14 moving towards the second arm 15.

FIG. 2B illustrates a schematic diagram of the second arm 15 moving towards the first arm 14.

FIG. 3A illustrates a schematic diagram of the photomask flipping mechanism 10 holding the photomask 8.

FIG. 3B illustrates a three-dimensional diagram of the photomask flipping mechanism 10 holding the photomask 8.

FIG. 4A illustrates a schematic diagram of another implementation of the photomask flipping mechanism 20.

FIG. 4B illustrates a schematic diagram of the photomask flipping mechanism 20 holding the photomask 8.

FIG. 4C illustrates a schematic diagram of another implementation of the photomask flipping mechanism 30.

FIG. 5 illustrates a flowchart of the photomask cleaning method of this implementation.

FIG. 6 illustrates a schematic diagram of the transport mechanism 9 transporting the photomask 8.

FIG. 7A illustrates a schematic diagram of the photomask protective film 8M with the first surface facing down.

FIG. 7B illustrates a schematic diagram of the first arm 14 and the second arm 15 flipping the photomask to make the first surface of the photomask protective film 8M face up.

FIG. 7C illustrates a schematic diagram of the first arm 14 and the second arm 15 flipping the photomask to make the first surface of the photomask protective film 8M face down.

FIG. 8 illustrates a schematic diagram of the mechanical arm 70 connected to the photomask flipping mechanism 10.

### DETAILED DESCRIPTION

In order to describe in detail the technical content, structural features, achieved objectives and effects of the instant application, the following detailed descriptions are given in conjunction with the drawings and specific embodiments. It should be understood that these embodiments are only used to illustrate the application and not to limit the scope of the instant application.

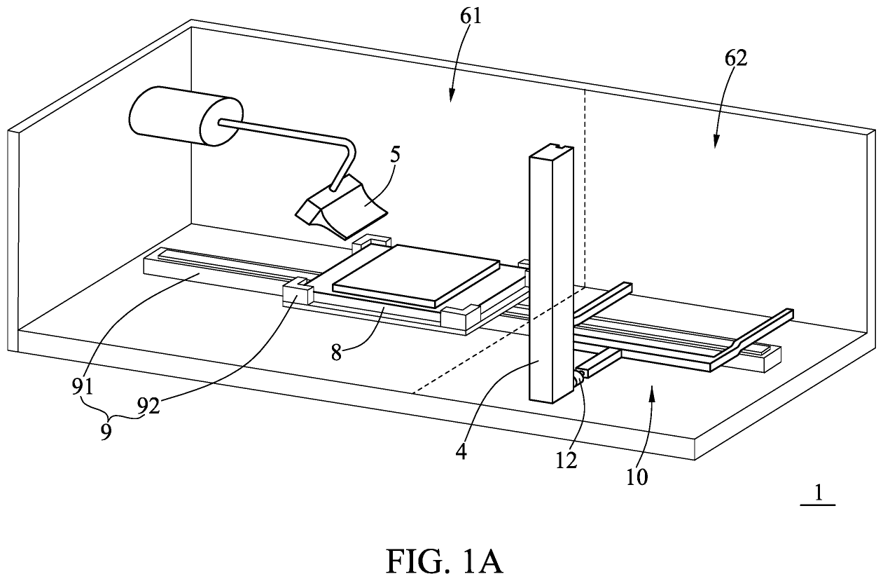

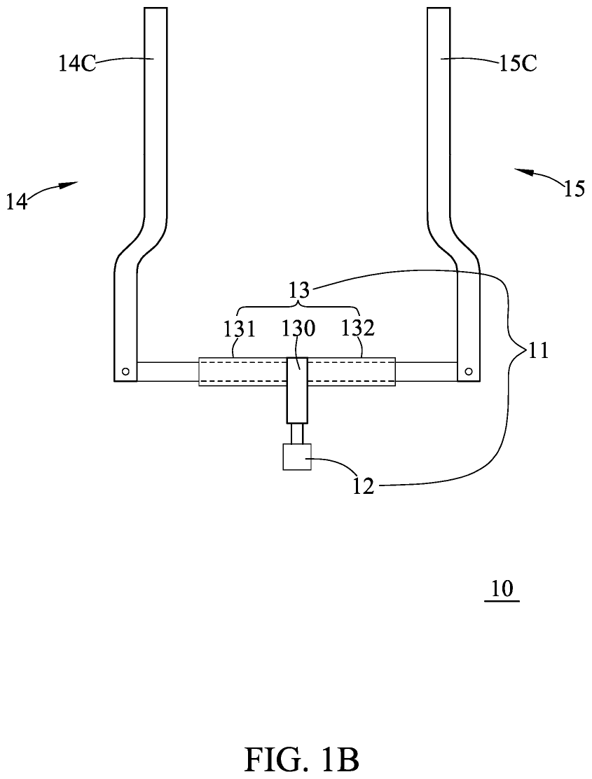

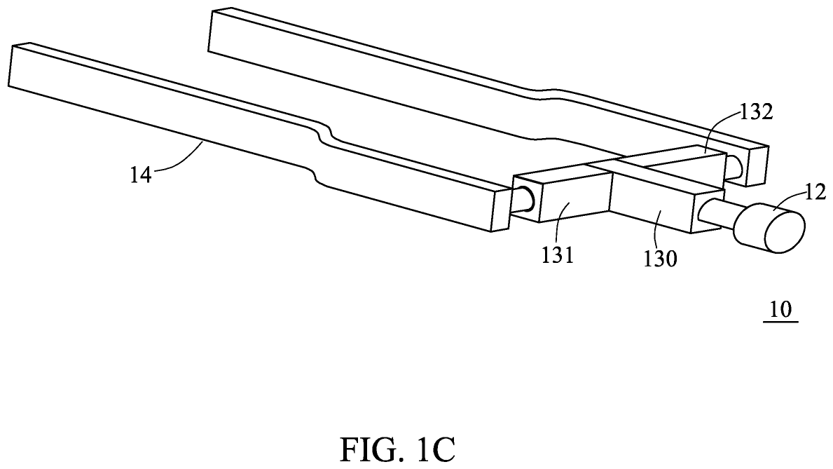

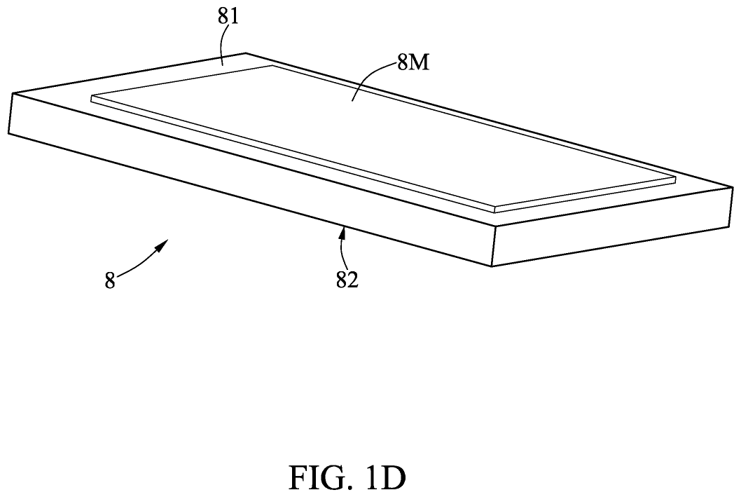

Refer to FIGS. 1A to 1D, FIG. 1A is a schematic diagram of the photomask cleaning device 1 in this implementation. FIG. 1B is a schematic diagram of the photomask flipping mechanism 10 in this implementation, FIG. 1C is a three-dimensional diagram of the photomask flipping mechanism 10, and FIG. 1D is a schematic diagram of the photomask 8.

The photomask cleaning device 1 in this implementation is suitable for cleaning a photomask 8. The vacuum interior of the photomask cleaning device 1 is equipped with a cleaning area 61 and a photomask flipping area 62. The photomask 8 has a first surface 81 and a second surface 82, and a pattern and a photomask protective film 8M are set on the first surface 81. The photomask protective film 8M covers the pattern. The photomask cleaning device 1 also includes a photomask flipping mechanism 10, a transport mechanism 9, and a cleaning mechanism 5. In this implementation, the photomask flipping mechanism 10 is located in the photomask flipping area 62, and the photomask flipping mechanism 10 is used to flip the photomask 8. More specifically, the photomask flipping mechanism 10 includes a flipping part 11, a first arm 14, and a second arm 15. The flipping part 11 includes a rotating part 12 and a support part 13, and the support part 13 includes a body 130, a first telescopic member 131, and a second telescopic member 132. The first telescopic member 131 and the second telescopic member 132 can be controlled to extend and retract using known techniques such as cylinders, hydraulic cylinders, or motors. Among them, the flipping part 11 is used to flip the first arm 14 and the second arm 15. Specifically, the body 130 of the support part 13 is connected to the rotating part 12, and the first arm 14 and the second arm 15 are opposite to each other. In addition, the rotating part 12 of the flipping part 11 has a driving member that can drive the support part 13 to be lifted or lowered and rotated, so as to simultaneously lift or lower and flip the first arm 14 and the second arm 15. In another implementation, the photomask flipping mechanism 10 also includes a lifting mechanism 4. The rotating part 12 has a rotating function, and the lifting mechanism 4 is connected to the rotating part 12 of the photomask flipping mechanism 10. The lifting mechanism 4 has a driving element such as a motor to drive the lifting. The lifting mechanism 4 is connected to the rotating part 12 of the photomask to lift the photomask flipping mechanism 10 to a height. In this way, the photomask flipping mechanism 10 that has risen to a height has enough space to flip, and can lower the height to place the photomask 8 on the transport mechanism 9 or clamp the photomask 8 on the transport mechanism 9.

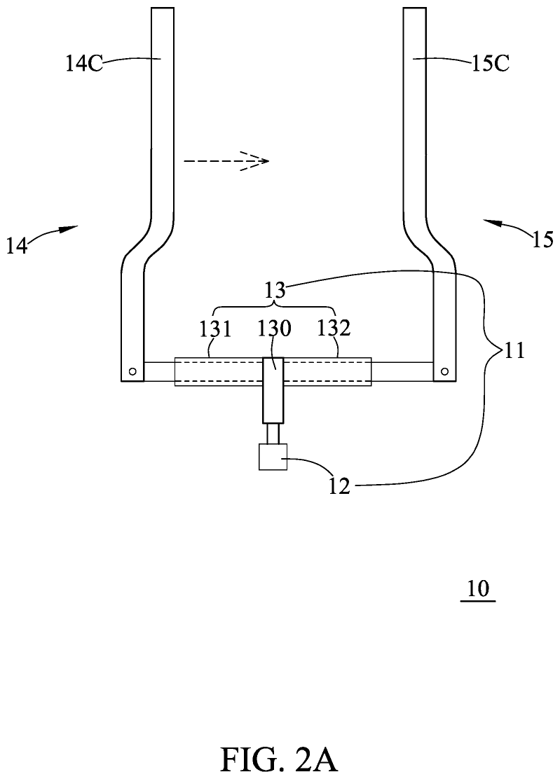

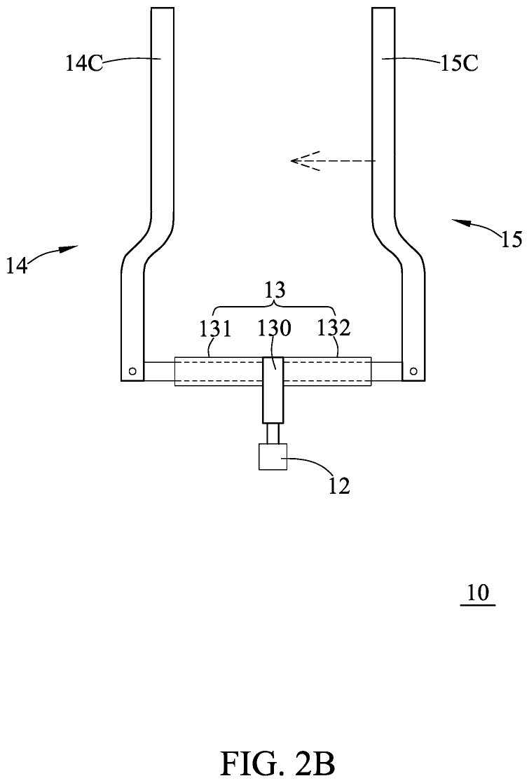

Refer to FIG. 2A, FIG. 2A is a schematic diagram of the first arm 14 moving towards the second arm 15. The first arm 14 is connected to one side of the support part 13, and the first arm 14 includes a first holding part 14C. The second arm 15 is connected to the other side of the support part 13, and the second arm 15 includes a second holding part 15C, and the first holding part 14C and the second holding part 15C are parallel to one another. Specifically, one end of the first telescopic member 131 is connected to the body 130, and the other end of the first telescopic member 131 is connected to the first arm 14. Therefore, the first arm 14 can move relative to the second arm 15 through the first telescopic member 131.

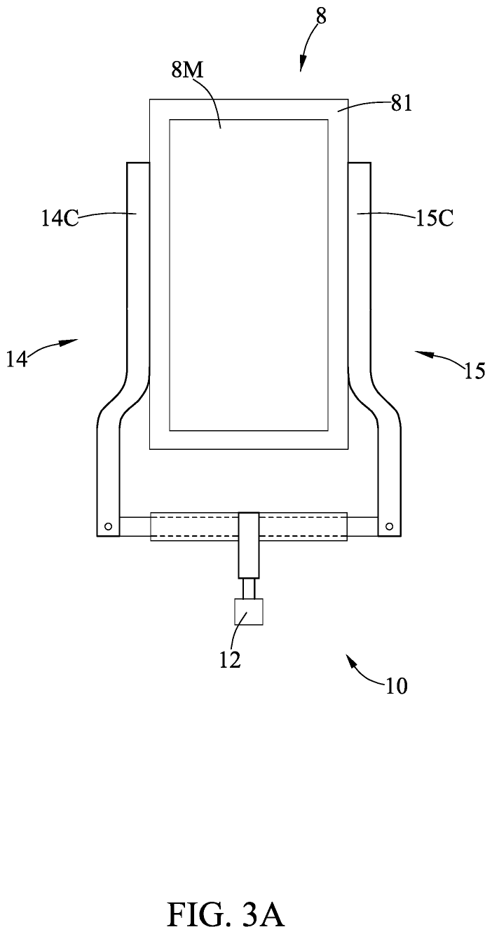

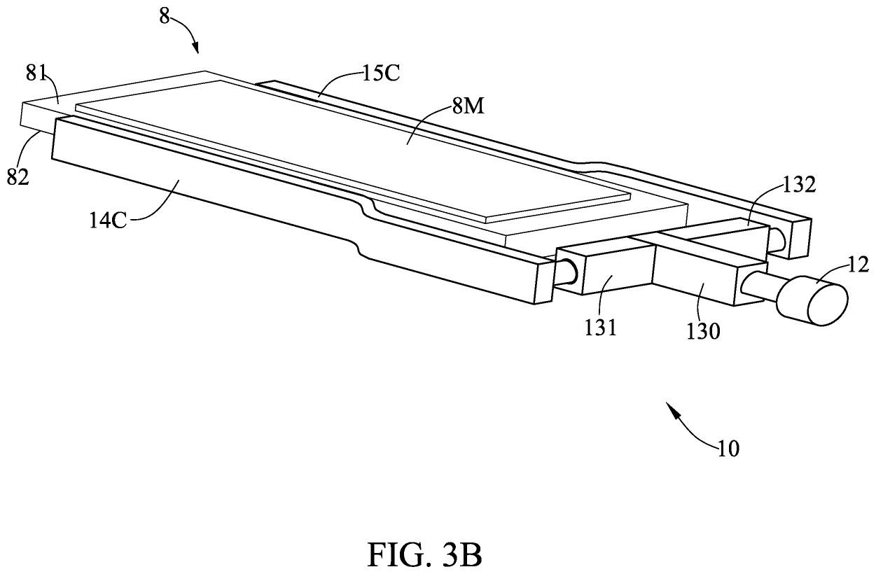

Refer to FIG. 2B, FIG. 2B is a schematic diagram of the second arm 15 moving towards the first arm 14. One end of the second telescopic member 132 is also connected to the body 130, and the other end of the second telescopic member 132 is connected to the second arm 15. Similarly, the second arm 15 can also move relative to the second arm 15 through the second telescopic member 132. In other words, the first arm 14 and the second arm 15 can move relative to one another. In this way, the first holding part 14C of the first arm 14 and the second holding part 15C of the second arm 15 can firmly hold the photomask 8 (refer to FIGS. 3A and 3B).

In addition, the first arm 14 is equipped with the first holding part 14C, and the second arm 15 is equipped with the second holding part 15C. The distance between the first holding part 14C and the second holding part 15C is less than the average distance between the first arm 14 and the second arm 15. Therefore, when the first holding part 14C and the second holding part 15C hold the photomask 8, the part of the first arm 14 that does not belong to the first holding part 14C and the part of the second arm 15 that does not belong to the second holding part 15C do not touch the photomask 8.

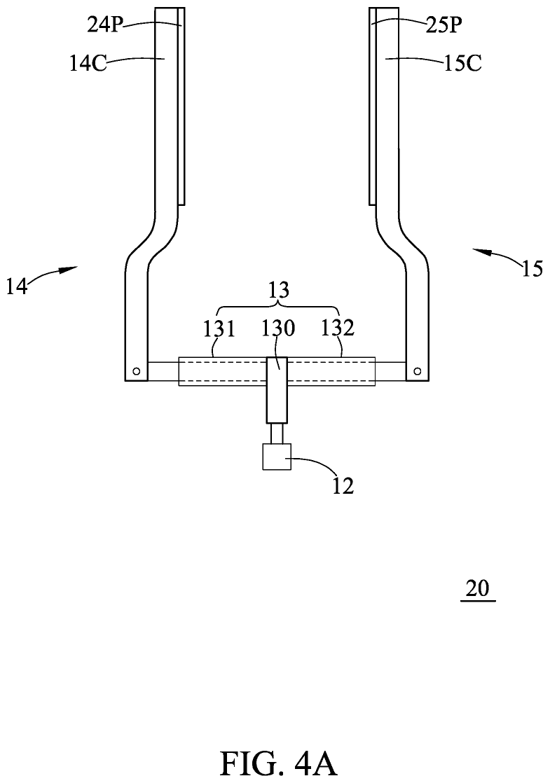

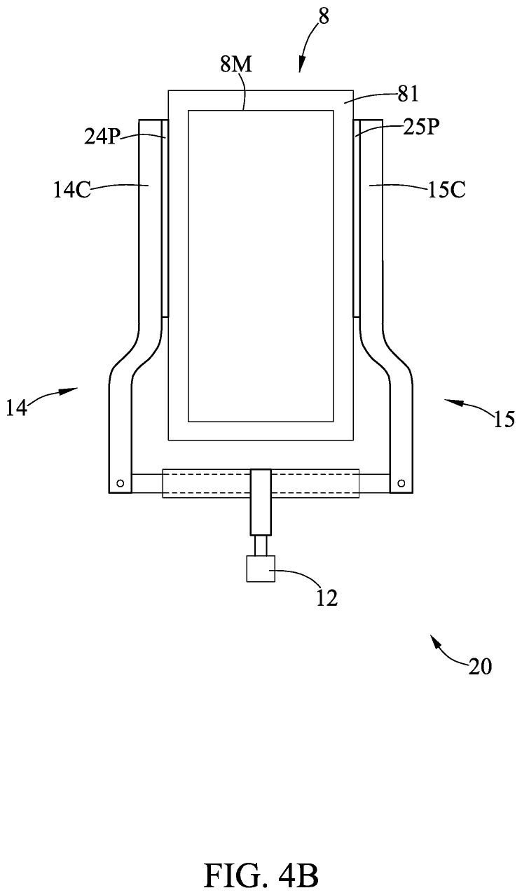

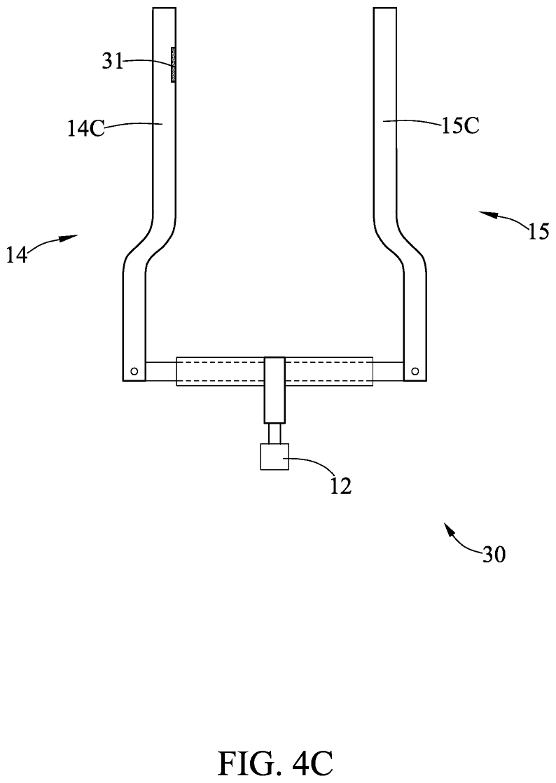

Refer to FIGS. 4A and 4B, FIG. 4A is a schematic diagram of another implementation of the photomask flipping mechanism 20. The difference between the photomask flipping mechanism 20 and the photomask flipping mechanism 10 is that: the photomask flipping mechanism 20 also includes a first dust-free cushion 24P and a second dust-free cushion 25P. Among them, the first dust-free cushion 24P and the second dust-free cushion 25P are respectively set on the side of the first holding part 14C and the second holding part 15C that can contact the photomask 8, and the material of the first dust-free cushion 24P and the second dust-free cushion 25P is for example anti-static foam or clean room dedicated foam.

In this implementation, when the first holding part 14C holds the photomask 8, the first dust-free cushion 24P will contact the photomask 8. Similarly, when the second holding part 15C holds the photomask 8, the second dust-free cushion 25P contacts the photomask 8. Therefore, when the photomask flipping mechanism 20 holds the photomask 8, it can prevent the photomask 8 from being damaged.

FIG. 4C is a schematic diagram of another implementation of the photomask flipping mechanism 30. The photomask flipping mechanism 30 adds a pressure sensor 31 to the photomask flipping mechanism 10, that is, a pressure sensor 31 is set on the first holding part 14C of the first arm 14 of the photomask flipping mechanism 30. Because when the force of holding the photomask 8 is too tight, the photomask 8 that is rubbed or hit will also produce pollutants. Therefore, by detecting and controlling the force of the first arm 14 and the second arm 15 holding the photomask 8 through the pressure sensor 31, it can prevent the force of holding the photomask 8 from being too large and prevent the production of pollutants. In this implementation, the pressure sensor 31 is located on the first arm 14. However, in other implementations, the pressure sensor 31 can also be located on the second arm 15, and can also detect the force of the first arm 14 and the second arm 15 holding the photomask 8. Or, a pressure sensor 31 can also be set on the first arm 14 and the second arm 15 respectively, which can more accurately detect the force of holding the photomask 8.

Refer to FIG. 1A, the transport mechanism 9 is used to transport the photomask 8, enabling the photomask 8 to move between the photomask flipping area 62 and the cleaning area 61. Specifically, the transport mechanism 9 includes a rail 91 and a photomask carrier 92, the rail 91 connects the photomask flipping area 62 and the cleaning area 61. In addition, the photomask carrier 92 is assembled on the rail 91 in a movable manner by a driving element such as a motor, and the photomask carrier 92 is used to carry the photomask 8. In this way, the transport mechanism 9 can transport the photomask 8, and the photomask flipping mechanism 10 just has to flip the photomask 8 within the photomask flipping area 62.

Furthermore, the cleaning mechanism 5 is located within the cleaning area 61, the cleaning mechanism 5 is used to clean the photomask 8, the cleaning mechanism 5 is, for example, an air knife device, a static neutralization device, or an ultrasonic resonance device. In this implementation, the cleaning mechanism 5 is exemplified by an air knife device. In other implementations, the photomask cleaning device 1 can also simultaneously include multiple different types of cleaning mechanisms 5, for example, it can simultaneously have an air knife device, a static neutralization device, and an ultrasonic resonance device.

The lifting mechanism 4 and the photomask flipping mechanism 10, the transport mechanism 9, the cleaning mechanism 5, etc. mentioned above are all connected to a control circuit, which is used to automate operations, allowing the photomask 8 to move between the cleaning area 61 and the photomask flipping area 62, and to clean in the cleaning area 61 and flip in the photomask flipping area 62.

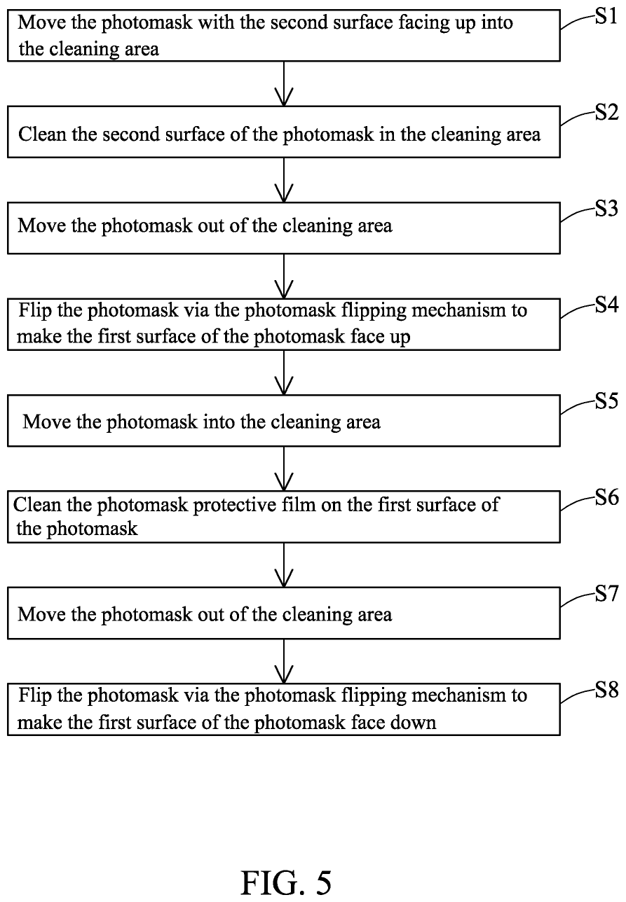

The above content mainly discloses the structure of the photomask cleaning device 1 and the photomask flipping mechanism 10, and the following will explain how to clean the photomask 8 by the photomask flipping mechanism 10 of the photomask cleaning device 1 with reference to FIG. 5.

Refer to FIG. 5, FIG. 5 is a flowchart of the photomask cleaning method of this implementation. The photomask cleaning method includes the following steps:

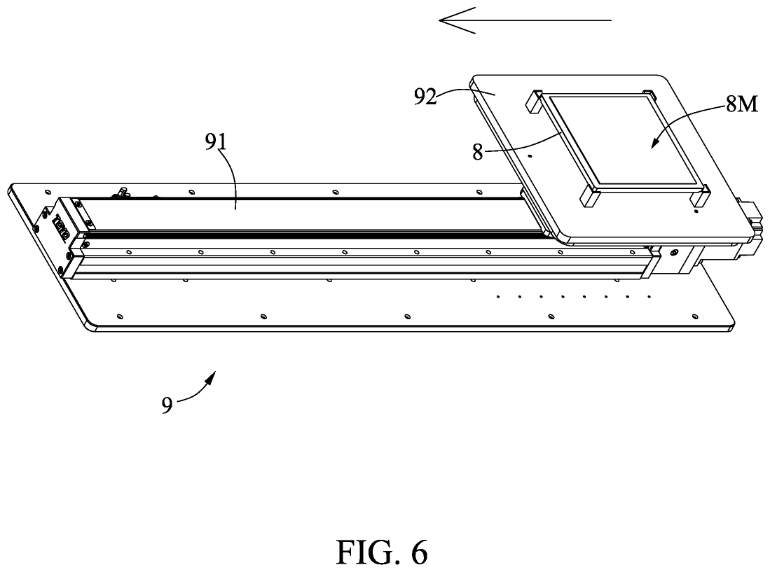

First, refer to FIG. 1A, FIG. 6 and step S1, move the photomask 8 into the cleaning area 61. Specifically, the photomask 8 with the second surface 82 facing up is moved from the outside of the cleaning device 1 into the vacuum interior through the transport mechanism 9, first passing through the photomask flipping area 62 and then moving into the cleaning area 61.

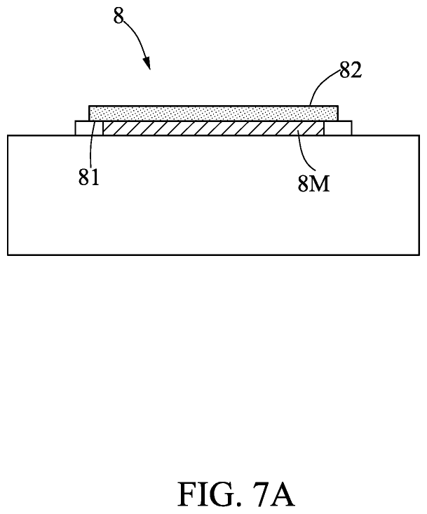

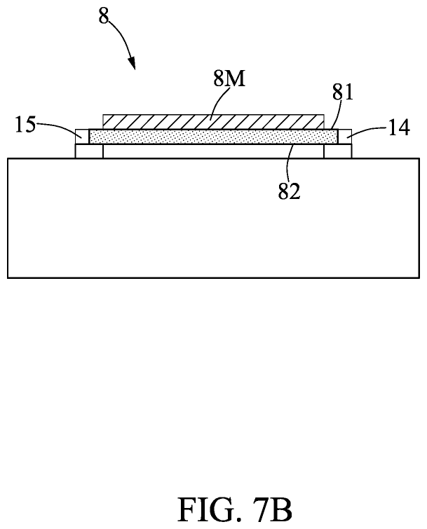

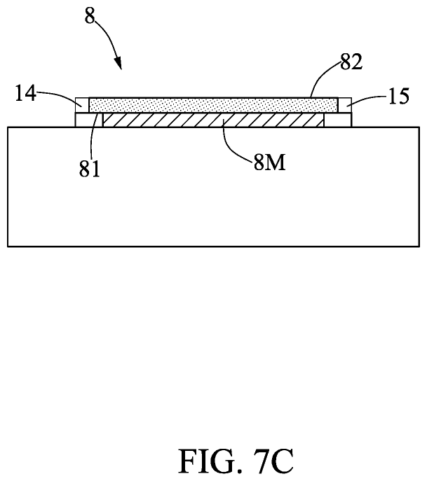

Then, refer to FIG. 7A and step S2, clean the second surface 82 of the photomask 8 in the cleaning area 61. Specifically, when the photomask 8 is not flipped, the first surface 81 of the photomask 8 is facing down, so the second surface 82 of the photomask 8 will face upwards, so the cleaning mechanism 5 (air knife device, static neutralization device, and ultrasonic resonance device) can first clean the second surface 82 of the photomask 8.

Next, refer to step S3, move the photomask 8 out of the cleaning area 61. Specifically, after cleaning the second surface 82 of the photomask 8, the transport mechanism 9 then moves the photomask 8 from the cleaning area 61 to the photomask flipping area 62.

Then, refer to FIG. 7B and step S4, flip the photomask 8 via the photomask flipping mechanism 10 to make the first surface 81 of the photomask 8 face up. Specifically, in the photomask flipping area 62, the first arm 14 and the second arm 15 of the photomask flipping mechanism 10 hold the two sides of the photomask 8, and the rotating part 12 is lifted or the lifting mechanism 4 moves the photomask 8 from the photomask carrier 92 to a height that can be flipped, and then the rotating part 12 flips the support part 13 in the photomask flipping area 62 to drive the photomask 8 to flip at the same time, and then the rotating part 12 or the lifting mechanism 4 places the photomask 8 on the photomask carrier 92, so that the first surface 81 of the photomask 8 faces up.

Next, refer to step S5, move the photomask 8 into the cleaning area 61. Specifically, the first arm 14 and the second arm 15 will first move away from the photomask 8 by the rotating part 12 or the lifting mechanism 4. Then, the transport mechanism 9 moves the photomask 8 from the photomask flipping area 62 into the cleaning area 61. In this way, the first surface 81 of the photomask 8 in the cleaning area 61 is facing up.

Then, refer to step S6, clean the photomask protective film 8M on the first surface 81 of the photomask 8. Among them, when the photomask 8 is moved into the cleaning area 61, the cleaning mechanism 5 (air knife device, static neutralization device, and ultrasonic resonance device) then cleans the photomask protective film 8M. Therefore, compared to the method of cleaning one side, the photomask cleaning method of this implementation can effectively clean the first surface 81 and the second surface 82 of the photomask 8, and can prevent the contaminants on the second surface 82 of the photomask 8 from adhering to the photomask protective film 8M, and also prevent contaminants from entering between the photomask protective film 8M and the photomask 8.

Next, refer to step S7, move the photomask 8 out of the cleaning area 61. Specifically, after cleaning the photomask protective film 8M, the transport mechanism 9 then moves the photomask 8 from the cleaning area 61 to the photomask flipping area 62.

Then, refer to FIG. 7C and step S8, flip the photomask 8 via the photomask flipping mechanism 10 to make the first surface 81 of the photomask 8 face down. Specifically, the first arm 14 and the second arm 15 of the photomask flipping mechanism 10 once again hold the two sides of the photomask 8, and the rotating part 12 is lifted or the lifting mechanism 4 moves the photomask 8 from the photomask carrier 92 to a height that can be flipped, and then the rotating part 12 flips the support part 13 to drive the photomask 8 to flip at the same time, and then the rotating part 12 or the lifting mechanism 4 places the photomask 8 on the photomask carrier 92, so that the first surface 81 of the photomask 8 faces down. In this way, the photomask 8 is restored to the state before cleaning.

This implementation example can increase the number of cleanings as needed, for example, repeat steps S1 to S8 once or multiple times, to increase the cleaning effect of the photomask. In addition, you can also repeat steps S1 to S3 alone, that is, perform steps S1-S2-S3-S4-S5-S6-S7-S8-S1-S2-S3 in sequence, to enhance the cleaning effect of the second surface 82 of the photomask 8.

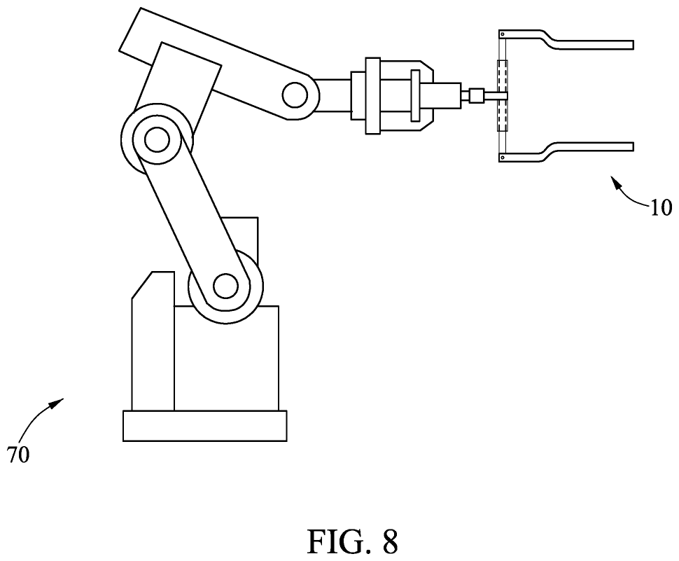

Refer to FIG. 8, the photomask flipping mechanism 10 is connected to a mechanical arm 70, the photomask flipping mechanism 10 holds the two sides of the photomask 8 through the first arm 14 and the second arm 15, and the mechanical arm 70 is used to drive the photomask flipping mechanism 10 to move the photomask 8 away from the carrier 92, and flip the photomask 8 and then put it back on the carrier 92. Specifically, the mechanical arm 70 can replace the lifting mechanism 4 in FIG. 1A, the mechanical arm 70 can also raise and lower the height of the photomask flipping mechanism 10, the photomask flipping mechanism 10 that has risen to a height has enough space to flip, and can lower the height to place the photomask 8 on the transport mechanism 9 or clamp the photomask 8 on the transport mechanism 9.

In another implementation, the mechanical arm 70 can move in the cleaning area and the flipping area, in this way, the photomask flipping mechanism 10 can simultaneously drive the photomask 8 into the cleaning area 61. Similarly, the photomask flipping mechanism 10 can also move the photomask 8 out of the cleaning area 61 through the mechanical arm 70.

In summary, the photomask cleaning device, photomask flipping mechanism, and photomask cleaning method of the present disclosure can help clean the first surface 81 and the second surface 82 of the photomask 8.

Although the present disclosure has been disclosed and illustrated with reference to particular embodiments, the principles involved are susceptible for use in numerous other embodiments that will be apparent to a person having ordinary skill in the art. This disclosure is, therefore, to be limited only as indicated by the scope of the appended claims.

What is claimed is:

1. A photomask cleaning device for cleaning a photomask, the photomask having a first surface and a second surface, wherein the first surface includes a pattern and a photomask protective film covering the pattern, the photomask cleaning device comprising:
a photomask flipping mechanism located within a photomask flipping area, the photomask flipping mechanism configured to flip the photomask;
a transport mechanism for transporting the photomask, enabling the photomask to move between the photomask flipping area and a cleaning area; and
at least one cleaning mechanism located within the cleaning area, the cleaning mechanism configured to clean the photomask.

2. The photomask cleaning device of claim 1, wherein the photomask flipping mechanism comprises:
a first arm including a first holding part;
a second arm including a second holding part; and
a flipping part, connecting the first arm and the second arm, the flipping part configured to flip the first arm and the second arm, wherein the first arm and the second arm are movable relative to one another.

3. The photomask cleaning device of claim 2, wherein the photomask flipping mechanism further comprises a lifting mechanism, the lifting mechanism connected to the flipping part of the photomask flipping mechanism.

4. The photomask cleaning device of claim 1, wherein the transport mechanism comprises:
a rail, connecting the photomask flipping area and the cleaning area; and
a photomask carrier, assembled on the rail in a movable manner, wherein the photomask is carried on the photomask carrier.

5. The photomask cleaning device of claim 1, wherein the cleaning mechanism comprises at least one of an air knife device, a static neutralization device, or an ultrasonic resonance device.

6. A photomask flipping mechanism for flipping a photomask, the photomask having a first surface and a second surface, wherein the first surface includes a pattern and a photomask protective film covering the pattern, the photomask flipping mechanism comprising:
a first arm including a first holding part;
a second arm including a second holding part; and
a flipping part, connecting the first arm and the second arm, the flipping part configured to flip the first arm and the second arm, wherein the first arm and the second arm are movable relative to one another, enabling the first holding part and the second holding part to hold the photomask.

7. The photomask flipping mechanism of claim 6, wherein the flipping part comprises:
a rotating part; and
a support part, connected to the rotating part, wherein the rotating part is configured to flip the support part.

8. The photomask flipping mechanism of claim 7, wherein the first arm is located on one side of the support part, and the second arm is located on the other side of the support part.

9. The photomask flipping mechanism of claim 7, wherein the support part comprises:
a body;
a first telescopic member, one end of which is connected to the body, the other end of the first telescopic member connected to the first arm; and
a second telescopic member, one end of which is connected to the body, the other end of the second telescopic member connected to the second arm.

10. The photomask flipping mechanism of claim 6, further comprising a first dust-free cushion and a second dust-free cushion, wherein the first dust-free cushion and the second dust-free cushion are respectively arranged on the first holding part and the second holding part, and when the photomask flipping mechanism holds the photomask, the first dust-free cushion and the second dust-free cushion are in contact with the photomask.

11. The photomask flipping mechanism of claim 6, wherein the distance between the first holding part and the second holding part is less than the average distance between the first arm and the second arm.

12. The photomask flipping mechanism of claim 6, wherein at least one pressure sensor is arranged on the first arm or the second arm.

13. A photomask cleaning method for cleaning a photomask using the photomask flipping mechanism of claim 7, wherein the photomask has a first surface and a second surface, and a photomask protective film is arranged on the first surface, the photomask cleaning method comprising the steps of:
moving the photomask with the second surface facing up into a cleaning area;
cleaning the second surface of the photomask in the cleaning area;
moving the photomask out of the cleaning area;
flipping the photomask via the photomask flipping mechanism to make the first surface of the photomask face up;
moving the photomask into the cleaning area;
cleaning the photomask protective film on the first surface of the photomask;
moving the photomask out of the cleaning area; and
flipping the photomask via the photomask flipping mechanism to make the first surface of the photomask face down.

14. The photomask cleaning method of claim 13, wherein the photomask is moved into and out of the cleaning area via a transport mechanism.
